(19) United States
(12) Patent Application Publication
(10) Pub. No.: US 2017/0077234 A1
(43) Pub. Date: Mar. 16, 2017

(54) DEVICES AND METHODS OF CREATING ELASTIC RELAXATION OF EPITAXIALLY GROWN LATTICE MISMATCHED FILMS

(71) Applicant: GLOBALFOUNDRIES Inc., Grand Cayman (KY)

(72) Inventors: Neeraj TRIPATHI, Albany, NY (US); Srinivasa R. BANNA, San Jose, CA (US)

(73) Assignee: GLOBALFOUNDRIES Inc., Grand Cayman (KY)

(21) Appl. No.: 14/853,303

(22) Filed: Sep. 14, 2015

(51) Int. Cl. H01L 29/161; H01L 21/02; H01L 29/06; H01L 21/762

(52) U.S. Cl. CPC H01L 29/161; H01L 21/76208; H01L 21/02142; H01L 21/02236; H01L 21/0245; H01L 21/02532; H01L 29/0649

(57) ABSTRACT

Devices and methods of creating elastic relaxation of epitaxially grown lattice mismatched films for semiconductor devices are provided. One method includes, for instance: obtaining a wafer including a substrate; epitaxially growing at least one first silicon germanium (SiGe) layer over the wafer; and epitaxially growing at least one second SiGe layer over the at least one first SiGe layer. One device includes, for instance: a wafer including a substrate; at least one first layer of semiconductor material disposed over the wafer; at least one second layer of semiconductor material disposed over the at least one first layer of semiconductor material; and at least one first and second openings, each opening extending through the at least one second layer of semiconductor material, the at least one first layer of semiconductor material, and a portion of the substrate.

### FIELD OF THE INVENTION

The present invention relates to semiconductor devices and methods of fabricating semiconductor devices, and more particularly, to devices and methods of creating elastic relaxation of epitaxially grown lattice mismatched films.

### BACKGROUND OF THE INVENTION

Generally, in order to achieve strain relaxation in the epitaxial layers, intentional damage is induced in lattice mismatched epitaxial structures. When damage is intentionally induced, however, it becomes difficult to keep the defect density to an acceptable low level due to the intentional creation of implant damage to the epitaxial heterostructure. A dislocation propagation stopper layer may be inserted to stop the propagation of dislocation with further epitaxial growths. A thick buffer layer may be grown to reduce the number of dislocation that reach the surface. However, it remains difficult to achieve full relaxation in thin epitaxial layers. Therefore, it may be desirable to develop methods for achieving more complete relaxation of lattice mismatched films in thinner hetero structures.

### BRIEF SUMMARY

The shortcomings of the prior art are overcome and additional advantages are provided through the provision, in one aspect, a method that includes, for instance: obtaining a wafer including a substrate; epitaxially growing at least one first silicon germanium (SiGe) layer on the wafer; and epitaxially growing at least one second SiGe layer on the at least one first SiGe layer.

In another aspect, a semiconductor device is provided which includes, for instance: a wafer including a substrate; at least one first layer of semiconductor material disposed over the wafer; at least one second layer of semiconductor material disposed over the at least one first layer of semiconductor material; and at least one first and second openings, each opening extending through the at least one second layer of semiconductor material, the at least one first layer of semiconductor material, and a portion of the substrate.

Additional features and advantages are realized through the techniques of the present invention. Other embodiments and aspects of the invention are described in detail herein and are considered a part of the claimed invention.

### BRIEF DESCRIPTION OF THE SEVERAL VIEWS OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIG. 1 depicts one embodiment of a method of creating elastic relaxation of epitaxially grown lattice mismatched films, in accordance with one or more aspects of the present invention;

FIG. 2 depicts a cross-sectional elevation view in a first direction of one embodiment of a semiconductor device including a substrate and at least one first silicon germanium (SiGe) layer, in accordance with one or more aspects of the present invention;

FIG. 3 depicts the structure of FIG. 2 after the at least one second SiGe layer is epitaxially grown on the at least one first SiGe layer, in accordance with one or more aspects of the present invention;

FIG. 4A depicts the structure of FIG. 3 after etching at least one first opening extending through the at least one second SiGe layer, the at least one first SiGe layer, and a portion of the substrate, in accordance with one or more aspects of the present invention;

FIG. 4B depicts a cross-sectional elevation view in a second direction of the structure of FIG. 3 after etching at least one second opening extending through the at least one second SiGe layer, the at least one first SiGe layer, and a portion of the substrate, in accordance with one or more aspects of the present invention;

FIG. 4C depicts the top plan view of structure of FIG. 4B showing the at least one first opening as a groove in a first direction and the at least one second opening as a groove in a second direction, with FIG. 4A being the cross-sectional view taken along line 4A-4A and with

FIG. 4B being the cross-sectional view taken along line 4B-4B, in accordance with one or more aspects of the present invention;

FIG. 5 depicts the structure of FIG. 4C after depositing at least one oxide layer over the device and filling the at least one first and second openings, in accordance with one or more aspects of the present invention;

FIG. 6 depicts the structure of FIG. 5 after performing an oxidation process, in accordance with one or more aspects of the present invention;

FIG. 7 depicts the structure of FIG. 6 after planarizing the at least one oxide layer, in accordance with one or more aspects of the present invention; and

FIG. 8 depicts the structure of FIG. 7 after depositing at least one third SiGe layer on the wafer, in accordance with one or more aspects of the present invention.

### DETAILED DESCRIPTION

Aspects of the present invention and certain features, advantages, and details thereof, are explained more fully below with reference to the non-limiting embodiments illustrated in the accompanying drawings. Descriptions of well-known materials, fabrication tools, processing techniques, etc., are omitted so as to not unnecessarily obscure the invention in detail. It should be understood, however, that the detailed description and the specific examples, while indicating embodiments of the invention, are given by way of illustration only, and are not by way of limitation. Various substitutions, modifications, additions and/or arrangements within the spirit and/or scope of the underlying inventive concepts will be apparent to those skilled in the art from this disclosure. Note also that reference is made below to the drawings, which are not drawn to scale for ease of understanding, wherein the same reference numbers used throughout different figures designate the same or similar components.

Generally stated, disclosed herein are certain semiconductor devices, which provide advantages over the above noted, existing semiconductor devices and fabrication processes. Advantageously, the semiconductor device fabrication processes disclosed herein provide for semiconductor devices with an increase in mobility and direct flow of current.

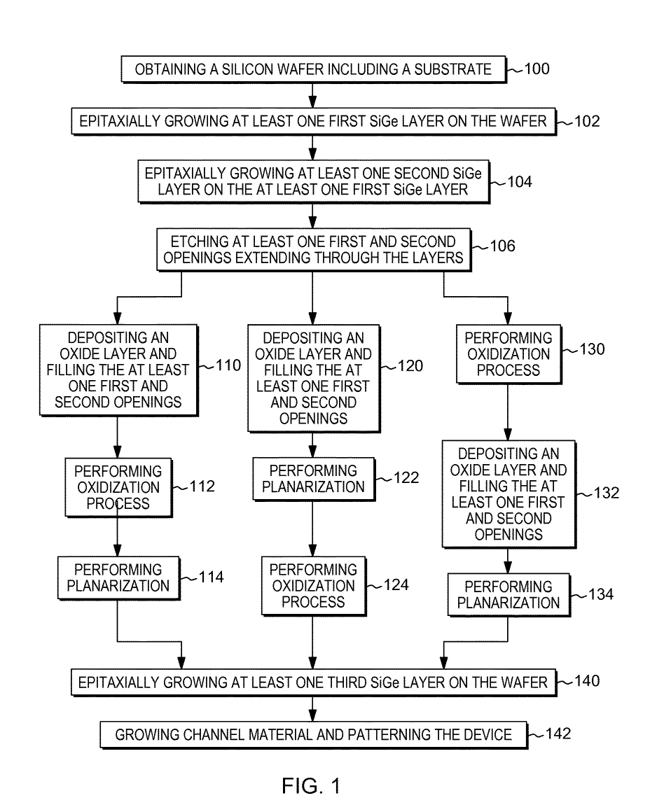

In one aspect, in one embodiment, as shown in FIG. 1, a semiconductor device formation process in accordance with one or more aspects of the present invention may include, for instance: obtaining a silicon wafer including a substrate 100; epitaxially growing at least one first SiGe layer on the wafer 102; epitaxially growing at least one second SiGe layer on the at least one first SiGe layer 104; etching at least one first and second openings extending through the layers 106; depositing at least one oxide layer and filling the at least one first and second openings 110; performing an oxidation process 112; performing planarization 114; epitaxially growing at least one third SiGe layer on the wafer 140; and growing channel material and patterning the device 142.

In another aspect, in one embodiment, as shown in FIG. 1, a semiconductor device formation process in accordance with one or more aspects of the present invention may include, for instance: obtaining a silicon wafer including a substrate 100; epitaxially growing at least one first SiGe layer on the wafer 102; epitaxially growing at least one second SiGe layer on the at least one first SiGe layer 104; etching at least one first and second openings extending through the layers 106; depositing at least one oxide layer and filling the at least one first and second openings 120; performing planarization 122; performing an oxidation process 124; epitaxially growing at least one third SiGe layer on the wafer 140; and growing channel material and patterning the device 142.

In another aspect, in one embodiment, as shown in FIG. 1, a semiconductor device formation process in accordance with one or more aspects of the present invention may include, for instance: obtaining a silicon wafer including a substrate 100; epitaxially growing at least one first SiGe layer on the wafer 102; epitaxially growing at least one second SiGe layer on the at least one first SiGe layer 104; etching at least one first and second openings extending through the layers 106; performing an oxidation process 130; depositing at least one oxide layer and filling the at least one first and second openings 132; performing planarization 134; epitaxially growing at least one third SiGe layer on the wafer 140; and growing channel material and patterning the device 142.

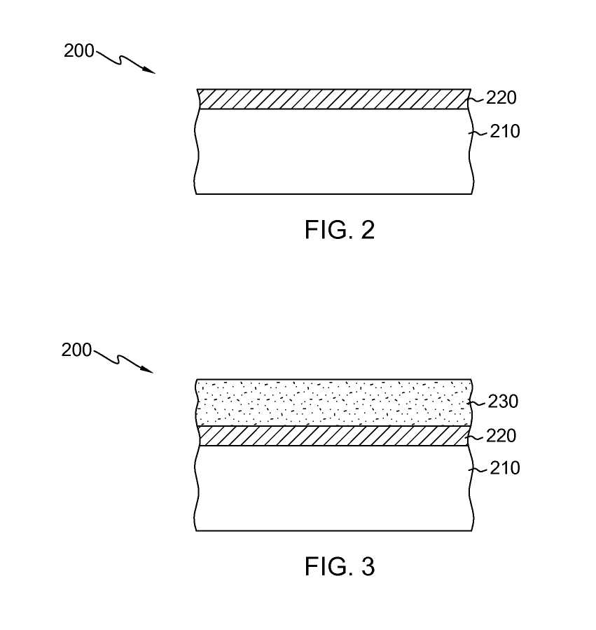

FIGS. 2-8 depict, by way of example only, one detailed embodiment of a portion of the semiconductor device formation process and an intermediate semiconductor structure, in accordance with one or more aspects of the present invention. Note that these figures are not drawn to scale in order to facilitate understanding of the invention, and that the same reference numerals used throughout different figures designate the same or similar elements.

FIG. 2 shows a portion of a semiconductor device 200 obtained during the fabrication process. The semiconductor device 200 may have been processed through initial device processing steps in accordance with the design of the device being fabricated, for example, the device 200 may include, for example, a substrate 210. The substrate 210 may in some embodiments have or be a substantially crystalline substrate material, such as silicon. The device 200 may be a wafer made of, for example, a semiconductor material, e.g., silicon (Si), germanium (Ge), a compound semiconductor material, and a layered semiconductor material, with or without dopants. The device 200 may also include at least one source region (not shown), and at least one drain region (not shown).

As used herein, the term “SiGe” or “silicon germanium” refers generally to the alloy having any molar ratio of silicon and germanium, with a molecular formula of the form Si₁₋ₓGeₓ.

As depicted in FIG. 2, the semiconductor device 200 may have at least one first SiGe layer 220 epitaxially grown over the substrate 210. In certain embodiments, the concentration of germanium in the at least one first SiGe layer ranges between 35% to approximately 100%, preferably between 45% to approximately 100%, and more preferably the concentration of germanium in the at least one first SiGe layer is equal to or greater than 50%. A first SiGe layer having a higher germanium concentration may be desirable for more selective oxidation process than a SiGe having a lower germanium concentration or a layer including only silicon.

As shown in FIG. 3, at least one second SiGe layer 230 may be epitaxially grown over the at least one first SiGe layer 220. In certain embodiments, the concentration of germanium in the at least one second SiGe layer ranges between approximately 0% to 50%, preferably between 20% to 40%, and more preferably the concentration of germanium in the at least one second SiGe layer is less than 50%.

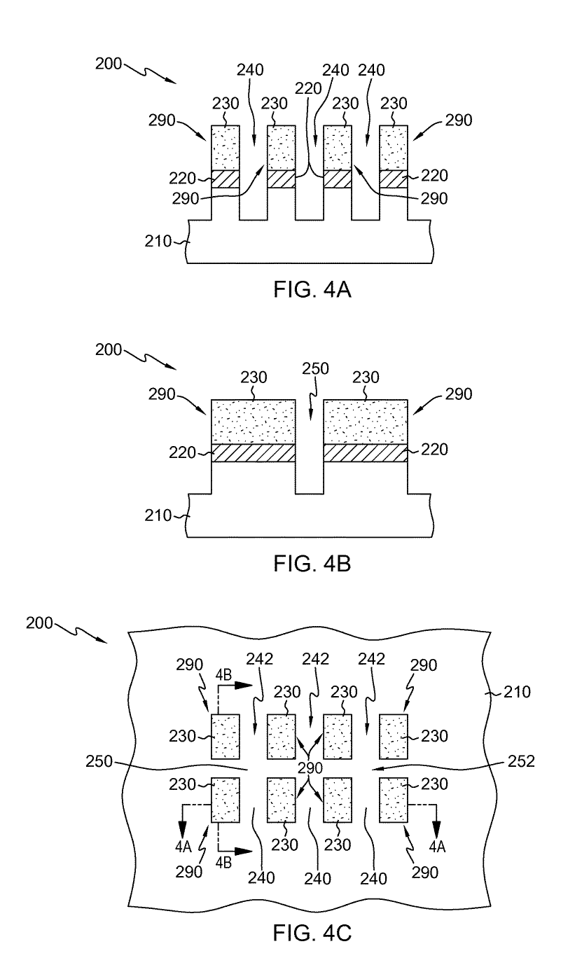

As depicted in FIGS. 4A and 4B, at least one opening 240, 250 may be formed. The at least one opening 240, 250 may extend through the at least one second SiGe layer 230, at least one first SiGe layer 220, and a portion of the substrate 210. The at least one opening 240, 250 may be formed by, for example, etching. The at least one first opening 240 and the at least one second opening 250 may be, for example, a groove, a trench, or a channel.

In certain embodiments, the at least one first opening 240 may be, for instance, a groove positioned in a first direction 242, extending the length of the device 200 in the first direction 242, as shown in FIG. 4C. The at least one second opening 250 may be, for instance, a groove positioned in a second direction 252, extending the length of the device 200 in the second direction 252. The groove positioned in a first direction 242 and the groove positioned in a second direction 252 may be, for example, perpendicular, as shown in FIG. 4C.

As depicted in FIG. 4C, the top view of the device 200 shows that the formation of the at least one first opening 240 and the at least one second opening 250 may result in the formation of island structures 290 having at least one second SiGe layer 230, at least one first SiGe layer 220, and a portion of the substrate 210. The island structures 290 may be formed to have appropriate length and width to allow for complete oxidation of the at least one first SiGe layer 220.

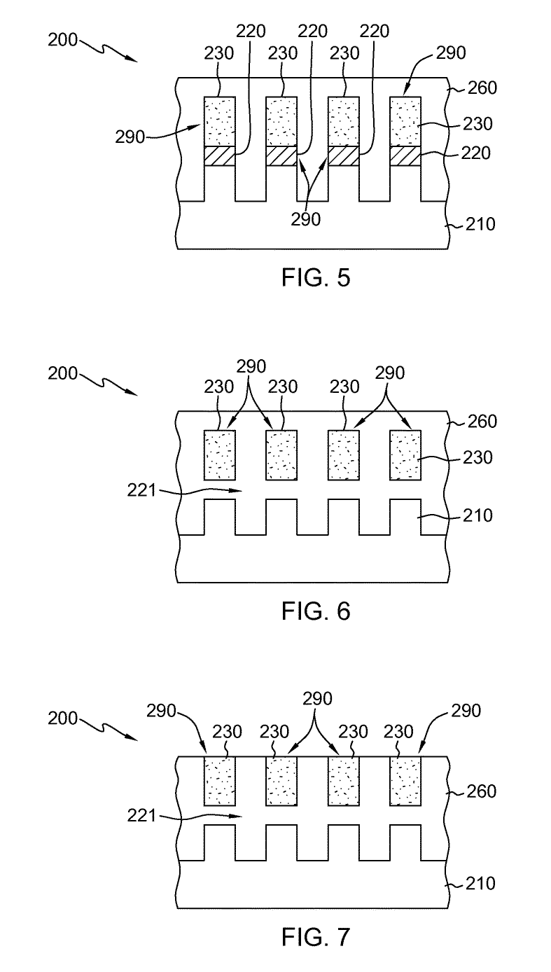

As depicted in FIG. 5, at least one oxide layer 260 may be deposited over the device 200 and fill the at least one first opening 240 and the at least one second opening 250. The at least one oxide layer 260 may be deposited using any conventional deposition process, for example, atomic layer deposition (ALD), chemical vapor deposition (CVD), or physical layer deposition (PVD). The at least one oxide layer 260 may be, for example, a silicon dioxide (SiO₂) layer or a germanium dioxide (GeO₂) layer.

As depicted in FIG. 6, an oxidation process may be performed. The at least one first SiGe layer 220, for example, a SiGe layer having a germanium concentration of ≧50%, may be selectively oxidized. The oxidation reaction of the at least one first SiGe layer 220 may result in the formation of an oxide layer 221, for example, a silicon germanium oxide layer, in the region occupied by the at least one first SiGe layer 220 and may result in the separation of the at least one second SiGe layer 230 and the substrate 210 by the oxide layer 221. Any conventional oxidation process may be performed, for example, thermal oxidation, such as rapid thermal oxidation (RTO), or in-situ steam growth (ISSG). One skilled in the art would understand that the oxidation process may include, for example, an annealing step. One skilled in the art would also understand that the oxidation process may involve, for example, exposure to high temperatures in the presence of oxygen.

As depicted in FIG. 7, the at least one oxide layer 260 may then be planarized by, for example, chemical mechanical planarization (CMP).

In certain embodiments, at least one oxide layer 260 may be deposited over the device 200 and fill the at least one first opening 240 and the at least one second opening 250, then the at least one oxide layer 260 may be planarized by, for example, CMP. The at least one oxide layer 260 may be deposited using any conventional deposition process identified above. The at least one oxide layer 260 may be, for example, a SiO₂ layer or a GeO₂ layer. After planarization, an oxidation process may be performed. The at least one first SiGe layer 220, for example, a SiGe layer having a germanium concentration of ≧50%, may be selectively oxidized. The oxidation reaction of the at least one first SiGe layer 220 may result in the formation of an oxide layer 221, i.e. a silicon germanium oxide layer, in the region occupied by the at least one first SiGe layer 220 and may result in the separation of the at least one second SiGe layer 230 and the substrate 210 by the oxide layer 221. Any conventional oxidation process may be performed as identified above.

In other embodiments, an oxidation process may be performed, then at least one oxide layer 260 may be deposited over the device 200, filling the at least one first opening 240 and the at least one second opening 250. The at least one oxide layer 260 may be deposited using any conventional deposition process identified above. The at least one first SiGe layer 220, for example, a SiGe layer having a germanium concentration of ≧50%, may be selectively oxidized. The oxidation reaction of the at least one first SiGe layer 220 may result in the formation of an oxide layer 221, for example, a silicon germanium oxide layer, in the region occupied by the at least one first SiGe layer 220 and may result in the separation of the at least one second SiGe layer 230 and the substrate 210 by the oxide layer 221. Any conventional oxidation process may be performed as identified above.

After the deposition, the at least one oxide layer 260 may be planarized by, for example, CMP.

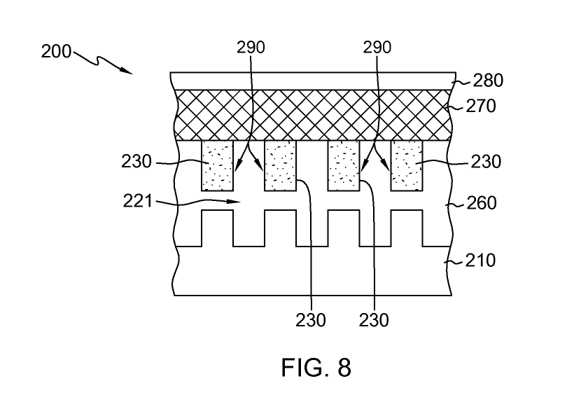

As depicted in FIG. 8, at least one third SiGe layer 270 may be epitaxially grown over the device 200. In certain embodiments, the concentration of germanium in the at least one third SiGe layer ranges between approximately 0% to 50%, preferably between 20% to 40%, and more preferably the concentration of germanium in the at least one second SiGe layer is less than 50%.

In certain embodiments, the at least one oxide layer 260 may be recessed by, for example, etching to expose a portion of the sidewalls of the at least one second SiGe layer 230. The at least one third SiGe layer 270 may be epitaxially grown over the device 200, and fill the etched portion of the at least one oxide layer 260.

In particular embodiments, at least one layer of channel material 280 may be grown over the at least one third SiGe layer 270, as shown in FIG. 8, and the at least one layer of channel material may then be patterned to fabricate any structure on the wafer, for example, fins, PFETs, and NFETs, in accordance with the device design.

The following paragraphs disclose another detailed embodiment of a portion of the semiconductor device formation process and an intermediate semiconductor structure, in accordance with one or more aspects of the present invention. The semiconductor device 200 including a substrate 210, may have at least one first SiGe layer 220 epitaxially grown over the substrate 210, and at least one second SiGe layer 230 may be epitaxially grown over the at least one first SiGe layer 220, as shown in FIG. 3. In certain embodiments, the concentration of germanium in the at least one first SiGe layer ranges between 35% to approximately 100%, preferably between 45% to approximately 100%, and more preferably the concentration of germanium in the at least one first SiGe layer is equal to or greater than 50%, and the concentration of germanium in the at least one second SiGe layer ranges between approximately 0% to 50%, preferably between 20% to 40%, and more preferably the concentration of germanium in the at least one second SiGe layer is less than 50%. At least one layer of channel material (not shown) may then be grown over the at least one second SiGe layer 230. The at least one layer of channel material may be patterned in accordance with the device design. Similar to the depictions in FIGS. 4A-4C, at least one opening 240, 250 may be formed, extending through the at least one layer of channel material, the at least one second SiGe layer 230 and the at least one first SiGe layer 220, and a portion of the substrate 210.

The at least one first opening 240 may be a groove positioned in a first direction 242, extending the length of the device 200 in the first direction 242, and the at least one second opening 250 may be a groove positioned in a second direction 252, extending the length of the device 200 in the second direction 252, similar to what is shown in FIG. 4C without the at least one layer of channel material shown. The groove positioned in a first direction 242 and the groove positioned in a second direction 252 may be perpendicular. The at least one first opening 240 and the at least one second opening 250 may be formed by, for example, etching.

In certain embodiments, at least one oxide layer 260 may be deposited over the device 200, filling the at least one first opening 240 and the at least one second opening 250. The at least one oxide layer 260 may be deposited using any conventional deposition process, for example, ALD, CVD, or PVD. The at least one oxide layer 260 may be, for example, a SiO₂ layer or a GeO₂ layer.

Next, an oxidation process may be performed. The at least one first SiGe layer 220, for example, a SiGe layer having a germanium concentration of ≧50%, may be selectively oxidized. The oxidation reaction of the at least one first SiGe layer 220 may result in the formation of an oxide layer 221, for example, a silicon germanium oxide layer, in the region occupied by the at least one first SiGe layer 220 and may result in the separation of the at least one second SiGe layer 230 and the substrate 210 by the oxide layer 221. Any conventional oxidation process may be performed, for example, thermal oxidation, such as rapid thermal oxidation (RTO), or in-situ steam growth (ISSG).

Then the at least one oxide layer 260 may then be planarized by, for example, CMP. The steps of depositing the at least one oxide layer 260, performing the oxidation process, and planarization may be performed in any order.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

1. A method comprising:
obtaining a wafer comprising a substrate;
epitaxially growing at least one first silicon germanium (SiGe) layer over the wafer;
epitaxially growing at least one second SiGe layer over the at least one first SiGe layer;
forming at least one opening extending through the at least one second SiGe layer, the at least one first SiGe layer, and a portion of the substrate;
depositing at least one oxide layer over the wafer and filling the at least one opening;
performing an oxidation process; and
planarizing the at least one oxide layer.

2. The method of claim 1, wherein the concentration of germanium in the at least one first SiGe layer is equal to or greater than 50% and the concentration of germanium in the at least one second SiGe is less than 50%

3. The method of claim 1, wherein the forming at least one opening extending through the at least one second SiGe layer, the at least one first SiGe layer, and a portion of the substrate comprises:
forming at least one first opening.

4. The method of claim 3, wherein the forming at least one opening extending through the at least one second SiGe layer, the at least one first SiGe layer, and a portion of the substrate further comprises:
forming at least one second opening extending through the at least one second SiGe layer, the at least one first SiGe layer, and a portion of the substrate,
wherein the at least one first opening is a groove positioned in a first direction and wherein the at least one second opening is a groove positioned in a second direction,
wherein the first direction is perpendicular to the second direction.

5. The method of claim 4, wherein the depositing at least one oxide layer over the wafer and filling the at least one opening comprises:
depositing at least one oxide layer over the wafer and filling the at least one first and second opening.

6. The method of claim 5, further comprising:
epitaxially growing at least one third SiGe layer on the wafer;
growing at least one layer of channel material over the at least one third SiGe layer; and
patterning the at least one layer of channel material.

7. The method of claim 6, wherein the concentration of germanium in the at least one third SiGe layer is less than 50%.

8. A method comprising:
obtaining a wafer comprising a substrate;
epitaxially growing at least one first silicon germanium (SiGe) layer over the wafer;
epitaxially growing at least one second SiGe layer over the at least one first SiGe layer;
growing at least one layer of channel material over the at least one second SiGe layer;
patterning the at least one layer of channel material; and
forming at least one opening extending through the at least one layer of channel material, the at least one second SiGe layer, the at least one first SiGe layer, and a portion of the substrate;
depositing at least one oxide layer over the wafer and filling the at least one opening;
performing an oxidation process; and
planarizing the at least one oxide layer.

9. The method of claim 8, further comprising wherein forming at least one opening comprises:
forming at least one first opening extending through the at least one layer of channel material, the at least one second SiGe layer, the at least one first SiGe layer, and a portion of the substrate, wherein the at least one first opening is a groove positioned in a first direction; and
forming at least one second opening extending through the at least one layer of channel material, the at least one second SiGe layer, the at least one first SiGe layer, and a portion of the substrate, wherein the at least one second opening is a groove positioned in a second direction;
wherein the first direction is perpendicular to the second direction.

10. The method of claim 9, wherein depositing at least one oxide layer over the wafer and filling the at least one opening comprises:
depositing at least one oxide layer over the wafer and filling the at least one first and second openings.

11. A semiconductor device comprising:
a wafer comprising a substrate;
at least one first layer of semiconductor material disposed over the wafer;
at least one second layer of semiconductor material disposed over the at least one first layer of semiconductor material; and
at least one first and second openings, each opening extending through the at least one second layer of semiconductor material, the at least one first layer of semiconductor material, and a portion of the substrate.

12. The semiconductor device of claim 11, wherein the at least one first layer of semiconductor material comprises oxide and wherein the at least one second layer of semiconductor material comprises silicon germanium (SiGe).

13. The semiconductor device of claim 11, wherein the at least one first layer of semiconductor material and the at least one second layer of semiconductor material are epitaxially grown.

14. The semiconductor device of claim 12, wherein the at least one first opening is a groove positioned in a first direction and the at least one second opening is a groove positioned in a second direction, and the first direction and the second direction are perpendicular

15. The semiconductor device of claim 14, wherein the at least one first and second openings are filled with oxide.

16. The semiconductor device of claim 14, further comprising:
at least one layer of channel material disposed over the at least one second layer of semiconductor material; and
the at least one first and second openings filled with oxide.

17. The semiconductor device of claim 14, further comprising:
at least one third layer of semiconductor material over the at least one second layer of semiconductor material; and
the at least one first and second openings filled with oxide.

18. The semiconductor device of claim 17, wherein the concentration of germanium in the at least one second layer and the at least one third layer of semiconductor material is less than 50%.

19. The semiconductor device of claim 18, wherein the at least one third layer of semiconductor material is epitaxially grown.

20. The semiconductor device of claim 19, further comprising:
at least one layer of channel material disposed over the at least one third layer of semi conductor material.
